(19) United States
(12) Patent Application Publication
(10) Pub. No.: US 2016/0372631 A1
(43) Pub. Date: Dec. 22, 2016

(54) LIGHT EMITTING DIODE

(71) Applicant: Panasonic Intellectual Property Management Co., Ltd., Osaka (JP)

(72) Inventors: YOSHIAKI HASEGAWA, Toyama (JP); YUSUKE TANJI, Osaka (JP); TOSHIYA FUKUHISA, Toyama (JP); MASANORI MICHIMORI, Toyama (JP); MASAYASU SAIGOU, Toyama (JP); YASUMITSU KUNOH, Toyama (JP); MASAHIRO KUME, Toyama (JP); YASUTOSHI KAWAGUCHI, Toyama (JP); TAKASHI KANO, Toyama (JP)

(21) Appl. No.: 15/250,979

(22) Filed: Aug. 30, 2016

Related U.S. Application Data
(63) Continuation of application No. PCT/JP2015/001467, filed on Mar. 17, 2015.

(30) Foreign Application Priority Data
Mar. 28, 2014 (JP) 2014-068184

(51) Int. Cl. H01L 33/06; H01L 33/12; H01L 33/32

(52) U.S. Cl. CPC H01L 33/06; H01L 33/32; H01L 33/12

(57) ABSTRACT

A light emitting diode includes a GaN substrate having a C-plane as a lamination surface; an n-type GaN layer which is laminated on the GaN substrate and which includes a first n-type GaN layer, an n-type intermediate layer, and a second n-type GaN layer; and an AlGaN strain adjustment layer laminated on the n-type GaN layer. Furthermore, the light emitting diode includes a light-emitting layer which is laminated on the AlGaN strain adjustment layer and which has a multi-quantum well structure having well layers and barrier layers, which are made of InGaN having a lattice constant in an a-axis direction larger than that of the AlGaN strain adjustment layer; and a p-type AlGaN cladding layer laminated on the light emitting layer.

### BACKGROUND

1. Technical Field

The present disclosure relates to a light emitting diode including a GaN substrate, an n-type GaN layer, a light-emitting layer having a multi-quantum well structure based on a gallium nitride-based semiconductor, and a p-type AlGaN layer.

2. Description of the Related Art

At present, light emitting diodes (LEDs) receive attention as white light sources for lighting. Development of light sources which make the most of merits as their characteristics such as low power consumption, light weight and downsizing with use of LEDs is advancing. Among these light sources, in automobile exterior light sources which are a mobile object field, LEDs widen individual design. Therefore, LEDs are becoming widespread as vehicle-mounted daytime running light (DRL). In future, LEDs are thought to rapidly spread as light sources of vehicle-mounted head lamps and to be employed as all vehicle-mounted lighting.

In vehicle-mounted LEDs, their long-term reliability is very important. LEDs in which a gallium nitride (GaN)-based semiconductor layer is laminated on a GaN substrate have a lower density of crystal defect than that of LEDs in which a GaN-based semiconductor layer is laminated on a different kind of substrate (e.g., sapphire substrate). Therefore, LEDs in which a GaN-based semiconductor layer is laminated on a GaN substrate receive attention.

Moreover, as an application of future vehicle-mounted head lamp, individual design is pursued in addition to long-term reliability. Therefore, while further downsizing is required in vehicle-mounted head lamp, appearance of LEDs capable of realizing a high light output (high luminous flux) even at a large current drive of an ampere level, in which a GaN-based semiconductor layer is laminated on a GaN substrate, is desired.

A light emitting diode described in PTL 1 is known as a light emitting diode including a GaN substrate and an n-type GaN layer, a light-emitting layer having a multi-quantum well (MQW) structure, and a p-type semiconductor layer laminated on the GaN substrate.

An photoelectron device described in PTL 1 includes an n-type GaN substrate having a semipolar plane (20-2-1) as a lamination surface, an n-type GaN layer, an n-type superlattice structure made of GaN and InGaN, a MQW active region formed by lamination of well layers including an InGaN layer and a barrier layer including a GaN layer, a p-type superlattice structure, and a p-type contact layer.

### CITATION LIST

### Patent Literature

PTL 1: WO 2013/049817 A

A crystal of a GaN-based semiconductor has piezoelectricity. That is, when stress is applied to the crystal, an electric field (piezo electric field) by polarization corresponding to the stress is generated in the crystal. For example, there is a defect below when an n-type GaN layer, and a light-emitting layer serving as a MQW active region having well layers including an InGaN layer and a barrier layer including a GaN layer are laminated on an n-type GaN substrate having a (0001) plane stable in crystallinity, that is, +C-plane (Ga-plane), as a lamination surface. That is, the light-emitting layer has a lattice constant in an a-axis direction larger than that of the n-type GaN layer, and therefore the light-emitting layer receives compression stress in the a-axis direction, that is, a direction parallel to the C-plane, and receives tensile stress in a c-axis direction, that is, a direction perpendicular to the C-plane. By these stress, a piezo electric field is generated within the light-emitting layer, particularly, within the well layer. By the piezo electric field, an electron is spatially separated from a hole within the well layer, resulting in a reduction in luminous efficiency. This phenomenon of a reduction in luminous efficiency is referred to as droop, and becomes a large problem since high luminous flux is hardly obtained even though LEDs are driven at a large current density.

In order to avoid and relax the piezo electric field, it is known that a nonpolar plane (M-plane, A-plane) and a semipolar plane are employed rather than a C-plane having polarity as a lamination surface of a substrate for lamination. In the photoelectron device described in PTL 1, a lamination surface is the semipolar plane (20-2-1), an n-type superlattice structrure made of GaN and InGaN is laminated between the n-type GaN layer and the MQW active region having the InGaN layer and the GaN layer, and In composition in an InGaN layer of a barrier layer is varied in a step-wise pattern.

However, in a case of the n-type GaN substrate having a semipolar plane of a substrate for lamination as a lamination surface, a Ga-plane and an N-plane coexist in the lamination surface, so that there is a problem that a GaN layer of high quality is hardly stably laminated in epitaxially growing a GaN layer on an n-type GaN substrate. Further, at present, a substrate for lamination having a nonpolar plane and a semipolar plane as a lamination surface is realized in a size of 2 inches; however, the substrate is unsuitable for commercial production since it is inferior in crystal quality and is very expensive in comparison with a C-plane substrate having a C-plane as a lamination surface. Accordingly, in the photoelectronic device described in PTL 1, it is significantly difficult to apply a light emitting diode of high quality to production.

### SUMMARY

Thus, it is an object of the present disclosure to provide a light emitting diode which can suppress luminous efficiency deterioration and can attain high quality even if a lamination surface of a GaN substrate is a C-plane.

A light emitting diode of the present disclosure includes a GaN substrate having a C-plane as a lamination surface, an n-type GaN layer laminated on the GaN substrate, an AlGaN layer laminated on the n-type GaN layer, a light-emitting layer which is laminated on the AlGaN layer and which has a multi-quantum well structure having well layers and at least one barrier layer both containing a gallium nitride-based semiconductor having a lattice constant in an a-axis direction larger than a lattice constant of the AlGaN layer in a-axis direction, and a p-type AlGaN layer laminated on the light-emitting layer.

According to the present disclosure, even if the lamination surface of the GaN substrate is a C-plane, strain generated in the light-emitting layer on the n-type GaN layer can be adjusted since the AlGaN layer is laminated between the n-type GaN layer and the light-emitting layer. Therefore, the effect that a droop phenomenon, that is, a reduction of luminous efficiency, can be suppressed and a light emitting diode of high quality is obtained is achieved.

### BRIEF DESCRIPTION OF THE DRAWINGS

FIG. 1 is a view showing a layer structure of a light emitting diode according to an exemplary embodiment of the present disclosure;

FIG. 2 is a view for explaining a lamination state of a light emitting diode shown in FIG. 1;

FIG. 3 is a graph showing a non-defective product yield due to electrical leakage with respect to a number of well layers;

FIG. 4 is a graph showing measurement results of the effect of improving an light output by introduction of a barrier layer made of InGaN and an increase of a well layer; and

FIG. 5 is a graph showing measurement results of the effect of reducing strain of a light-emitting layer by introduction of a barrier layer made of InGaN.

### DETAILED DESCRIPTION

A first aspect of the present disclosure includes a GaN substrate having a C-plane as a lamination surface, an n-type GaN layer laminated on the GaN substrate, an AlGaN layer laminated on the n-type GaN layer, a light-emitting layer laminated on the AlGaN layer, and a p-type clad layer laminated on the light-emitting layer. The light-emitting layer has a multi-quantum well structure having well layers and barrier layers respectively made of a gallium nitride-based semiconductor having a lattice constant in an a-axis direction larger than that of the AlGaN layer. The first aspect of the present disclosure is a light emitting diode.

According to the first aspect of the present disclosure, it is possible to suppress strain generated in the light-emitting layer by providing an AlGaN layer having a lattice constant in an a-axis direction smaller than that of the n-type GaN layer between the n-type GaN layer and the light-emitting layer made of the gallium nitride-based semiconductor to form a lamination structure of the n-type GaN layer, the AlGaN layer and the light-emitting layer. In other words, the AlGaN layer is a layer having a function of adjusting strain generated in the light-emitting layer in forming the light-emitting layer on the n-type GaN layer. Therefore, by disposing the light-emitting layer so as to be in contact with the AlGaN layer having a strain-adjustment function, a piezo electric field existing in the light-emitting layer, particularly the well layer, can be controlled. Hereinafter, the AlGaN layer having a strain-adjustment function may be referred to as an “AlGaN strain adjustment layer”.

A second aspect of the present disclosure is the light emitting diode in the first aspect of the present disclosure, wherein the AlGaN layer is formed so as to have a thickness of from 2 nm to 10 nm inclusive.

According to the second aspect of the present disclosure, if the thickness of the AlGaN layer is smaller than 2 nm, tensile stress applied to the light-emitting layer is small, so that strain control is difficult and an light output is deteriorated. On the other hand, if the thickness of the AlGaN layer is larger than 10 nm, tensile stress existing within the AlGaN layer increases and crystal quality tends to deteriorate, and in some cases rearrangement or cracks are produced in a crystal. Further, an effect of interference in supplying electron carriers from the n-type GaN layer also increases, and this leads to a reduction in efficiency of electron injection into the light-emitting layer and an increase of a driving voltage. Therefore, the AGaN layer is preferably formed so as to have a thickness of 2 nm to 10 nm.

A third aspect of the present disclosure is the light emitting diode in the first or second aspect of the present disclosure, wherein the light-emitting layer includes a semiconductor layer having a lattice constant in an a-axis direction larger than that of the n-type GaN layer.

According to the third aspect of the present disclosure, when the light-emitting layer is made of a semiconductor having a lattice constant in an a-axis direction larger than that of the n-type GaN layer, for example, InGaN, the light-emitting layer receives compression stress in a direction perpendicular to an A-plane (direction parallel to the C-plane), and receives tensile stress in a direction perpendicular to the C-plane. By the stress, the InGaN layer, the well layer of the light-emitting layer, generates a piezo electric field, and an electron is spatially separated from a hole within the well layer resulting in a reduction in luminous efficiency.

Here, the barrier layer constituting the light-emitting layer is made of a semiconductor having a lattice constant in an a-axis direction larger than that of the n-type GaN layer, for example, InGaN, a difference in lattice constant between the InGaN layer of the well layer and the barrier layer is decreased, and the piezo electric field generated in the well layer is largely relaxed. Since an electron and a hole in the well layer are efficiently recombined with each other by such an action, a reduction of luminous efficiency is suppressed. However, when the light-emitting layer is made of InGaN, an amount of In to be introduced into the barrier layer is preferably smaller than that in an In composition ratio of the well layer.

A fourth aspect of the present disclosure is the light emitting diode in any one of the first to third aspects of the present disclosure, wherein in the light-emitting layer, the semiconductor layer laminated on the AlGaN layer includes the well layer.

According to the fourth aspect of the present disclosure, since the semiconductor layer as the light-emitting layer in contact with the AlGaN layer includes the well layer, a light output can be increased and a defective product yield by electric leakage can be improved.

A fifth aspect of the present disclosure is the light emitting diode in any one of the first to fourth aspects of the present disclosure, wherein the AlGaN layer has an Al composition ratio of 1% to 5%.

According to the fifth aspect of the present disclosure, if the Al composition ratio of the AlGaN layer is less than 1%, tensile stress applied to the light-emitting layer is small, so that strain control is difficult and an light output is deteriorated. On the other hand, if the Al composition ratio of the AlGaN layer is larger than 5%, tensile stress existing within the AlGaN layer increases and crystal quality tends to deteriorate, and in some cases rearrangement or cracks are produced in a crystal. Further, the larger the Al composition ratio of the AlGaN layer is, the larger a barrier height of a conduction band between the n-type GaN layer and the AlGaN layer is, so that electron carriers are hard to be supplied from the n-type GaN layer to the light-emitting layer. Therefore, the excessively large Al composition ratio will lead to a reduction in efficiency of electron injection into the light-emitting layer and an increase of a driving voltage in the AlGaN layer. Accordingly, the Al composition ratio of the AlGaN layer is preferably 1% to 5%.

A sixth aspect of the present disclosure is the light emitting diode in any one of the first to fifth aspects of the present disclosure, wherein the well layer and the barrier layer are made of InGaN.

According to the sixth aspect of the present disclosure, since the well layer and the barrier layer are made of InGaN, a blue light emitting diode having a high light output can be formed.

A seventh aspect of the present disclosure is the light emitting diode in any one of the first to sixth aspects of the present disclosure, wherein the well layer made of InGaN has a total thickness of from 6 nm to 36 nm inclusive.

According to the seventh aspect of the present disclosure, if the total thickness of the well layer is smaller than 6 nm, a light-emitting volume is insufficient, and this leads to deterioration of a light output. On the other hand, if the total thickness of the well layer is larger than 36 nm, strain control of the well layer by the AlGaN layer is difficult, and this leads to deterioration of a light-emitting output. Moreover, if the total thickness of the well layer is larger than 36 nm, the total thickness of InGaN requiring low temperature growth more than GaN is excessive, and new crystal defects such as a lamination defect are produced and crystal quality of the light-emitting layer is deteriorated, and this leads to an increase of a defect in electric leakage. Accordingly, the total thickness of the well layer is preferably from 6 nm to 36 nm inclusive.

An eighth aspect of the present disclosure is the light emitting diode in any one of the first to seventh aspects of the present disclosure, wherein in a range of a current up to 2000 mA as a maximum injection current which flows from the p-type AlGaN layer to the n-type GaN layer, a shift amount of a center value of an emission wavelength relative to a center value at an injection current of 350 mA is 1 nm or less.

According to the eighth aspect of the present disclosure, a light emitting diode can be formed in which variation of the emission wavelength associated with a change of the injection current is suppressed.

### Exemplary Embodiment

A light emitting diode according to an exemplary embodiment of the present disclosure will be described with reference to drawing.

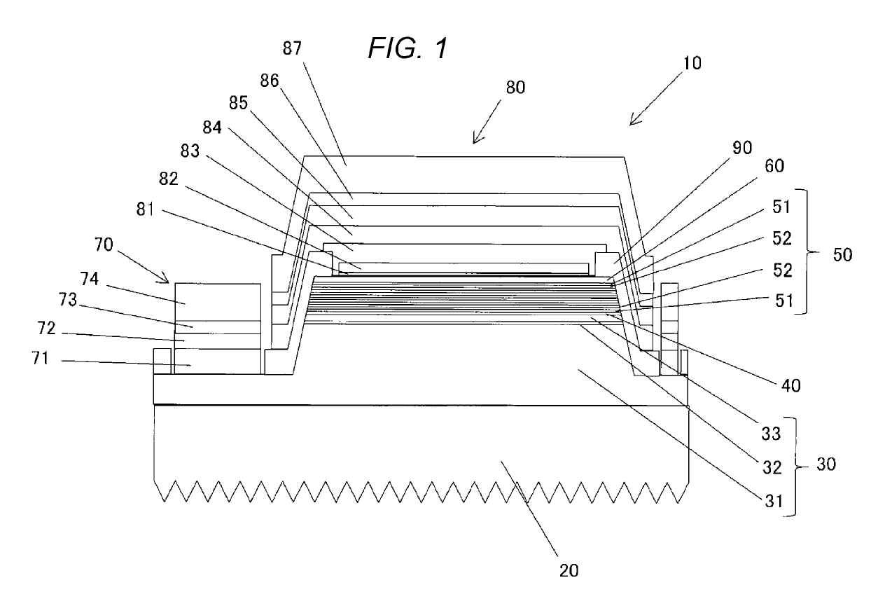

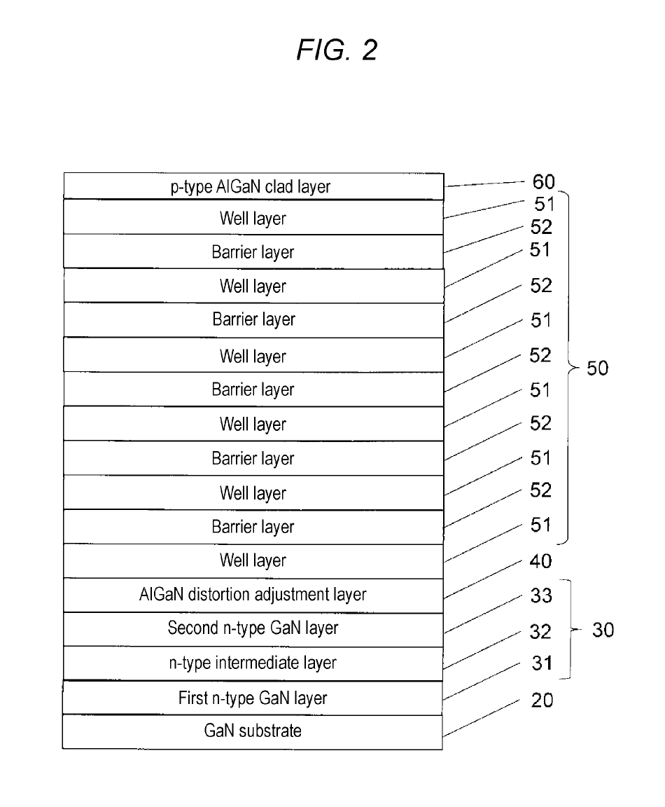

As shown in FIG. 1 and FIG. 2, light emitting diode 10 is an LED emitting blue light in which a center value of an emission wavelength is 425 nm to 465 nm (preferably, near to 445 nm). Light emitting diode 10 includes GaN substrate 20, n-type GaN layer 30, AlGaN strain adjustment layer 40, light-emitting layer 50, p-type AlGaN clad layer 60, n-side electrode 70, and p-side electrode 80.

GaN substrate 20 is made of n-type GaN. GaN substrate 20 can have a thickness of 50 μm to 200 μm. GaN substrate 20 has a (0001) plane, that is, a +C-plane (Ga-plane) as a lamination surface.

When semiconductor layers such as n-type GaN layer 30, AlGaN strain adjustment layer 40, light-emitting layer 50 and p-type AlGaN clad layer 60 are laminated on GaN substrate 20, it is possible to form a film by an epitaxial growth technology of a metalorganic vapor phase epitaxy (MOVPE) method, and it is also possible to perform lamination by, for example, epitaxial growth technologies such as a hydride vapor phase epitaxy (HVPE) method and a molecular beam epitaxy (MBE) method besides the MOVPE method.

n-type GaN layer 30 is laminated on GaN substrate 20. n-type GaN layer 30 includes first n-type GaN layer 31 made of GaN using silicon (Si) as an n-type dopant, n-type intermediate layer 32 made of AIInGaN doped with Si, and second n-type GaN layer 33 formed of GaN doped with Si.

First n-type GaN layer 31 is a contact layer constituting an n-side electrode. Second n-type GaN layer 33 is an electron supply layer for supplying electrons to light-emitting layer layer 50.

n-type GaN layer 30 can also use germanium (Ge) other than Si as the n-type dopant. First n-type GaN layer 31 can have a thickness of 500 nm to 5000 nm. The thickness is preferably 1000 nm to 2000 nm. n-type intermediate layer 32 can have a thickness of 5 nm to 100 nm. n-type GaN layer 33 can have a thickness of 10 nm to 1000 nm. The thickness of second n-type GaN layer 33 is preferably smaller than that of first n-type GaN layer 31 since second n-type GaN layer 33 needs to efficiently send electrons supplied from first n-type GaN layer 31 to light-emitting layer 50.

AlGaN strain adjustment layer 40 is an AlGaN laminated on second n-type GaN layer 33 of n-type GaN layer 30. AlGaN strain adjustment layer 40 is made of undoped AlGaN which forms a semiconductor layer having a lattice constant in an a-axis direction smaller than that of n-type GaN layer 30. AlGaN strain adjustment layer 40 can have a thickness of 2 nm to 10 nm. Further, AlGaN strain adjustment layer 40 can have an Al composition ratio of 1% to 5%. AlGaN strain adjustment layer 40 preferably has a relation that a film thickness is small if the Al composition ratio is high and a film thickness is large if the Al composition ratio is low.

If the Al composition ratio of AlGaN strain adjustment layer 40 is less than 1%, tensile stress applied to light-emitting layer 50 is small, so that strain control is difficult and a light output is deteriorated. On the other hand, if the Al composition ratio of AlGaN strain adjustment layer 40 is larger than 5%, tensile stress existing within AlGaN strain adjustment layer 40 increases and crystal quality tends to deteriorate, and in some cases rearrangement or cracks are produced in a crystal. Further, the larger the Al composition ratio of AlGaN strain adjustment layer 40 is, the larger a barrier height of a conduction band between AlGaN strain adjustment layer 40 and n-type GaN layer 30, so that electron carriers are hard to be supplied from n-type GaN layer 30 to light-emitting layer 50. Therefore, the excessively large Al composition ratio will lead to a reduction in efficiency of electron injection into light-emitting layer 50 and an increase of a driving voltage in AlGaN strain adjustment layer 40. Accordingly, the Al composition ratio of AlGaN strain adjustment layer 40 is preferably 1% to 5%.

Light-emitting layer 50 is laminated on AlGaN strain adjustment layer 40 and made of a gallium nitride-based semiconductor having a lattice constant in an a-axis direction larger than those of n-type GaN layer 30 and AlGaN strain adjustment layer 40.

Light-emitting layer 50 has a multiple quantum well structure of well layer 51 and barrier layer 52. Well layer 51 is made of undoped InGaN. Barrier layer 52 is made of undoped InGaN having In composition lower than that of well layer 51.

In light-emitting layer 50 of light emitting diode 10 according to the present exemplary embodiment, barrier layer 52 is interposed between well layers 51 to form a MQW active layer having a hexa-quantum well structure in which six layers of well layers 51 are laminated.

In light-emitting layer 50 in contact with AlGaN strain adjustment layer 40, a layer in contact with AlGaN strain adjustment layer 40 may be served as well layer 51 or may be served as barrier layer 52. In light-emitting layer 50 shown in FIG. 1 and FIG. 2, well layer 51 is laminated on AlGaN strain adjustment layer 40.

Well layer 51 can have a thickness of 2 nm to 12 nm. Here, the thickness of well layer 51 is preferably larger in order to reduce the effect of Auger non-radiative recombination due to a reduction of a density of injected carrier in the well layer, and is preferably 3 nm to 8 nm. Further, barrier layer 52 can have a thickness of 1 nm to 12 nm. The thickness of barrier layer 52 is preferably small contrary to well layer 51 in order to facilitate injection of holes having a heavy effective mass, and is preferably 1 nm to 3 nm.

Moreover, well layer 51 can have a total thickness (total film thickness) of 6 nm to 36 nm. If the total thickness of well layer 51 is smaller than 6 nm, a light-emitting volume is insufficient, and this leads to deterioration of an light output. On the other hand, if the total thickness of well layer 51 is larger than 36 nm, strain control of the well layer by AlGaN strain adjustment layer 40 is difficult, and this leads to deterioration of a light-emitting output. Moreover, if the total thickness of well layer 51 is larger than 36 nm, the total thickness of InGaN requiring low temperature growth more than GaN is excessive, and new crystal defects are produced and crystal quality of the light-emitting layer is deteriorated, and this leads to an increase of a defect in electric leakage.

P-type AlGaN clad layer 60 is a p-type AlGaN layer laminated on light-emitting layer 50. P-type AlGaN clad layer 60 is made of AlGaN using magnesium (Mg) as a p-type dopant.

N-side electrode 70 is disposed in a region on p-type AlGaN clad layer 60, light-emitting layer 50, AlGaN strain adjustment layer 40 and first n-type GaN layer 31 formed by etching a part of n-type GaN layer 30. N-side electrode 70 is formed by laminating Al (aluminum) layer 71, Ni (nickel) layer 72, Ti (titanium) layer 73 and Au (gold) layer 74.

p-side electrode 80 is disposed on p-type AlGaN clad layer 60 which is a remainder of etching. p-side electrode 80 is formed by laminating Ni layer 81, Ag (silver) layer 82, Ti layer 83, Al layer 84, Ni layer 85, Ti layer 86 and Au layer 87 in this order. Ag layer 82 on p-type AlGaN clad layer 60 functions as a reflection electrode which reflects and irradiates light emitted from light-emitting layer 50 toward GaN substrate 20 side.

A step boundary between p-type AlGaN clad layer 60 and exposed first n-type GaN layer 31 is covered and protected with insulating film 90 included of silicon dioxide (SiO₂). Insulating film 90 directly covers continuously from a top-face end to side surface of p-type AlGaN clad layer 60, a side surface of light-emitting layer 50, and a step of first n-type GaN layer 31.

In the light emitting diode according to the exemplary embodiment of the present disclosure thus configured, AlGaN strain adjustment layer 40 made of AlGaN is disposed between n-type GaN layer 30 made of GaN and light-emitting layer 50 made of InGaN. Light-emitting layer 50 made of the InGaN layer has a lattice constant in an a-axis direction larger than that of n-type GaN layer 30, so that when light-emitting layer 50 is laminated on n-type GaN layer 30 in a direct contact manner, in-plane compression stress is applied to light-emitting layer 50. It is possible to relax an in-plane strain generated in light-emitting layer 50 by laminating AlGaN strain adjustment layer 40 having a lattice constant in an a-axis direction smaller than that of n-type GaN layer 30 on n-type GaN layer 30 in a direct contact manner. As a result, it is possible to control strain existing in light-emitting layer 50 and a piezo electric field generated in the well layer due to the strain. This makes it possible to produce a light emitting diode suppressed in droop.

Since well layer 51 made of InGaN is laminated so as to be in contact with AlGaN strain adjustment layer 40, a light output can be increased and a non-defective product yield by electric leakage can be increased.

Even when a sapphire substrate is used, in-plane compression stress is applied to InGaN grown thereon; however, crystal defects such as penetrating dislocation are extremely numerous (dislocation density; about 1×10⁹ cm⁻²) and lattice relaxation proceeds, and therefore the compression stress is also relaxed. However, when GaN substrate 20 is used as a lamination substrate likewise light emitting diode 10 according to the present exemplary embodiment, the crystal defect is significantly few (dislocation density; about 5×10⁶ cm⁻²), and therefore large compression stress is applied to InGaN of light-emitting layer 50 grown thereon without lattice relaxation. Thus, the effect of strain control by AlGaN strain adjustment layer 40 is more remarkable than the case where the sapphire substrate is used.

AlGaN strain adjustment layer 40 is formed so as to have a thickness of 2 nm to 10 nm. For example, if AlGaN strain adjustment layer 40 has the same Al composition ratio and is formed having a thickness of several microns, there is a fear that new crystal defects or cracks are produced in AlGaN strain adjustment layer 40. If the thickness of AlGaN strain adjustment layer 40 is about a quarter of emission wavelength or more, that is, about 110 nm or more, emitted light is reflected on AlGaN strain adjustment layer 40 to be guided to a lamination in-plane direction because a refractive index of AlGaN strain adjustment layer 40 is smaller than that of light-emitting layer 50. Therefore, emission to a side of GaN substrate 20 is interfered to reduce an light output.

However, since AlGaN strain adjustment layer 40 is formed so as to have a thickness of 2 nm to 10 nm, a new crystal defect or crack is not produced in AlGaN strain adjustment layer 40.

If the thickness of AlGaN strain adjustment layer 40 is less than 2 nm, tensile stress applied to the light-emitting layer is small, so that strain control is difficult and an light output is deteriorated. On the other hand, if the thickness of AlGaN strain adjustment layer 40 is larger than 10 nm, tensile stress existing within AlGaN strain adjustment layer 40 increases and crystal quality tends to deteriorate, and in some cases rearrangement or cracks are produced in a crystal. Further, an effect of interference in supplying electron carriers from n-type GaN layer 30 also increases, and this leads to a reduction in efficiency of electron injection into the light-emitting layer and an increase of a driving voltage. Accordingly, the thickness of AlGaN strain adjustment layer 40 is preferably 2 nm to 10 nm.

If a sapphire substrate which is an example of an insulating substrate is used in place of GaN substrate 20 made of GaN, it is difficult to obtain a GaN film which has less defects such as penetrating dislocation due to lattice mismatch with n-type GaN layer 30 and a difference of thermal expansion coefficient.

Since the sapphire substrate is an insulating material, it is required that n-type GaN layer 30 into which electrons are injected has an impurity concentration of, for example, as high as 1×10¹⁸ cm⁻³ to 5×10¹⁸ cm⁻³, and n-type GaN layer 30 has a thickness of as thick as 5 μm to 8 μm. Accordingly, when light from light-emitting layer 50 is extracted from the sapphire substrate, the light is absorbed in n-type GaN layer 30 to be lost.

However, when GaN substrate 20 is made of GaN, GaN substrate 20 has the same material as in n-type GaN layer 30, and therefore light emitting diode 10 of high quality which has less defect can be obtained. Further, a +C-plane of GaN substrate 20 made of GaN is thermally stable, and when the +C-plane is used as a lamination surface, a crystal of high quality can be grown. Moreover, since GaN substrate 20 is electrically conductive, n-type GaN layer 30 can have a thickness of, for example, as thin as 1 to 2 m, and therefore light from light-emitting layer 50 can be efficiently extracted from a side of GaN substrate 20.

### Examples

Light emitting diode 10 shown in FIG. 1 was prepared, and optical properties and electrical properties thereof were evaluated. Hereinafter, each step will be described.

(Semiconductor Layer Lamination Step)

First, GaN substrate 20 is prepared which is a n-type GaN substrate having a (0001) plane, that is, a +C-plane (Ga-plane), as a main surface (lamination surface) in a wafer state.

GaN substrate 20 is held by a susceptor in a reaction furnace of a MOVPE apparatus, and the reaction furnace is evacuated. Subsequently, nitrogen (N₂), hydrogen (H₂) and ammonia (NH₃) were supplied to the reaction furnace so as to have a pressure of, for example, 20 kPa, and a temperature is increased to a growing temperature (for example, about 1000° C.).

Then, trimethyl gallium (TMG) and silane (SiH₄) gas serving as an n-type dopant were supplied simultaneously onto a main surface of GaN substrate 20 to grow first n-type GaN layer 31 having a thickness of 1500 nm. In this case, a silane gas amount was controlled so as to have a Si-doping concentration of 5×10¹⁸ cm⁻³.

Subsequently, after the temperature of the reaction furnace was lowered to about 850° C., trimethyl aluminum (TMA) and trimethyl indium (TMI) were also supplied in addition to TMG and the silane gas to grow n-type intermediate layer 32 made of n-type AlInGaN and having a thickness of 25 nm. In this case, a silane gas amount was controlled so as to have a Si-doping concentration of 5×10¹⁸ cm⁻³.

Next, after the temperature of the reaction furnace was increased to about 1000° C. again, TMG and silane gas were supplied simultaneously to grow second n-type GaN layer 33 having a thickness of 150 nm. In this case, a silane gas amount was controlled so as to have a Si-doping concentration of 5×10¹⁸ cm⁻³.

Subsequently, supply of the silane gas is stopped, and TMG and TMA are supplied to grow undoped AlGaN strain adjustment layer 40. Here, for example, when AlGaN strain adjustment layer 40 is doped with Si, AlGaN strain adjustment layer 40 physically becomes excessively firm, and therefore new crystal defects are introduced or cracks are produced. Accordingly, by making AlGaN strain adjustment layer 40 undoped, introduction of new crystal defects or occurrence of cracks can be suppressed, and crystal quality of light-emitting layer 50 to be subsequently formed can be maintained at a high level.

AlGaN strain adjustment layer 40 can have a thickness of 2 nm to 10 nm. Further, AlGaN strain adjustment layer 40 can have an Al composition ratio of 1% to 5%. In the present example, the thickness of AlGaN strain adjustment layer 40 is set to 5 nm, and the Al composition ratio of AlGaN strain adjustment layer 40 is set to 3%.

Next, after the temperature of the reaction furnace was lowered to about 850° C., TMG and TMI were supplied to grow well layer 51 made of undoped InGaN and having a thickness of 4 nm. In this case, growing is suspended until well layer 51 is grown, and the temperature is lowered from about 1000° C. to about 850° C. In order to obtain white light with use of a phosphor or the like, it is required to design a center value of an emission wavelength of light emitting diode 10 to a vicinity of 445 nm, and in the present example, this is realized by setting an In composition ratio of well layer 51 to about 15%.

Then, since the growth surface of well layer 51 is AlGaN strain adjustment layer 40, AlGaN has a lattice bond stronger than that of GaN, hardly forms a nitrogen void due to nitrogen leakage, and is excellent in heat resistance. Therefore, crystallinity of the surface of AlGaN strain adjustment layer 40 is kept high even in the aforementioned growing suspension. Accordingly, by disposing light-emitting layer 50 made of InGaN directly on AlGaN strain adjustment layer 40, light-emitting layer 50 of high quality can be laminated. In particular, in the present example, since well layer 51 made of InGaN and which contributes to light emission is laminated on AlGaN strain adjustment layer 40 in a direct contact manner, well layer 51 having high quality and good yield can be grown.

Subsequently, a supply amount of TMI is adjusted and barrier layer 52 made of InGaN and having a thickness of 3 nm was grown at In composition lower than that of well layer 51. In the present example, barrier layer 52 had an In composition ratio of about 30% to 65% of the In composition ratio (15%) of well layer 51, that is, the In composition ratio of barrier layer 52 was set to about 5% to 10%, and thereby compression stress of well layer 51 was reduced to relax a piezo electric field, so that a high light output was obtained.

If the In composition ratio of barrier layer 52 is less than 5%, a difference in In composition ratio between barrier layer 52 and well layer 51 is large, that is, lattice mismatch of barrier layer 52 with well layer 51 is large, and compression stress applied to well layer 51 is large, so that the piezo electric field is hardly relaxed. On the other hand, if the In composition ratio of barrier layer 52 is more than 10%, since a total In amount of light-emitting layer 50 as a whole is large, lattice mismatch of barrier layer 52 with base n-type GaN layer 30 and AlGaN strain adjustment layer 40 is excessively large. Accordingly, quality of light-emitting layer 50 is deteriorated, and thereby a light output obtained in light emitting diode 10 is deteriorated. In the present example, the In composition ratio of barrier layer 52 was set to 6%. Then, growths of well layer 51 and barrier layer 52 were alternately repeated to grow sextuple well layer. The In composition of well layer 51 in light-emitting layer 50 is controlled so that the center value of the emission wavelength is near 445 nm.

Next, after the temperature of the reaction furnace was increased to about 950° C., TMG and TMA were supplied, and simultaneously cyclopentadienyl magnesium (CP2Mg) serving as a p-type dopant was also supplied to grow p-type AlGaN layer 60 having a thickness of 120 nm. p-type AlGaN clad layer 60 has an Al composition ratio of 1% to 5%. When the Al composition ratio of p-type AlGaN clad layer 60 is the same as the Al composition ratio of AlGaN strain adjustment layer 40, stress applied to light-emitting layer 50 is balanced between a p-side and an n-side, and the effect of improving characteristics tends to be suitable.

After growth of p-type AlGaN clad layer 60, the temperature inside of the reaction furnace was lowered to room temperature while keeping supplies of hydrogen, nitrogen and ammonia. Then, the reaction furnace was evacuated, and then replaced with a purge gas, and GaN substrate 20 prepared by epitaxially growing a semiconductor layer including n-type GaN layer 30, AlGaN strain adjustment layer 40, light-emitting layer 50 and p-type AlGaN clad layer 60 was extracted from the reaction furnace.

Since all of the aforementioned films on GaN substrate 20 are laminated by epitaxial growth, a surface of each of the films is the same C-plane as in the surface of the GaN substrate.

(Electrode Formation Step)

Next, GaN substrate 20 on which a semiconductor layer was epitaxially grown was subjected to an electrode formation step of forming an electrode on GaN substrate 20. First, insulating film 90 made of SiO₂ is formed on an entire surface of p-type AlGaN clad layer 60 by a sputtering apparatus. Thereafter, the surface of p-type AlGaN clad layer 60 is etched by a dry etching apparatus until first n-type GaN layer 31 is exposed using, as a mask, insulating film 90 in which only a desired position is left by hydrofluoric acid treatment.

Thereafter, a part parallel to a C-plane with respect to insulating film 90 was removed to expose p-type AlGaN clad layer 60, and electrode layers of a Ni layer and an Ag layer were laminated in this order by a vapor deposition apparatus. Further, electrode layers of an Al layer, a Ni layer, a Ti layer, and an Au layer were formed in this order on exposed first n-type GaN layer 31 by a vapor deposition apparatus.

In order to enhance electrical contacting properties and adhesiveness between the electrode layer and each semiconductor layer, heat treatment of about 350° C. was performed in an atmosphere of nitrogen or oxygen, or in a mixed atmosphere of nitrogen and oxygen.

Subsequently, a Ti layer, an Al layer, a Ni layer, and further a Ti layer and an Au layer were vapor-deposited in this order on the Ag layer on p-type AlGaN clad layer 60. The Ti layer serving as a barrier layer suppresses diffusion of Au present above, and contributes to long-term stable driving of light emitting diode 10.

In this way, in the electrode formation step, Al layer 71, Ni layer 72, Ti layer 73, and Au layer 74 were laminated on first n-type GaN layer 31 to form n-side electrode 70. Further, Ni layer 81, Ag layer 82, Ti layer 83, Al layer 84, Ni layer 85, Ti layer 86 and Au layer 87 were laminated on p-type AlGaN clad layer 60 to form p-side electrode 80.

(Dicing Step)

A dicing step is a step of dividing GaN substrate 20 in a wafer state provided with n-side electrode 70 and p-side electrode 80 to be diced into each light emitting diode 10.

First, a back surface (−C-plane) opposite to the lamination surface of GaN substrate 20 was polished to reduce its thickness to about 100 μm, and wet-etched with a potassium hydroxide (KOH) solution. By this treatment, microscopic hexagonal pyramid-like irregularities are naturally formed on the back surface of GaN substrate 20. The microscopic irregularities contribute to effective extraction of light generated in light-emitting layer 50 to outside. Even when the same GaN substrate is used, if an M-plane is a lamination surface, such microscopic irregularities are not produced by chemical wet etching, and it is required to use expensive equipment such as dry etching. Accordingly, when GaN substrate 20 having a C-plane as a lamination surface is used, there is an advantage that high crystal quality can be ensured and processing of extracting light from the back surface of the substrate can be easily performed.

Next, GaN substrate 20 is cut along a scribing line by a laser scribing apparatus to obtain each light emitting diode 10. Light emitting diode 10 may be diced into a size of, for example, about 0.8 mm square.

(Inspection Step)

Light emitting diode 10 diced into a size of 0.8 mm square is flip-chip packaged on a submount element to extract light from light-emitting layer 50 from the back surface of GaN substrate 20. In this case, an electrode is arranged on the submount element, and by performing flip-chip packaging, n-side electrode 70 and p-side electrode 80 of light emitting diode 10 are electrically connected. When light emitting diode 10 is supplied with electric power, a current flows from p-type AlGaN clad layer 60 to n-type GaN layer 30.

When a high thermally conductive material such as Si, aluminum nitride (AIN) or copper (Cu) is used as the submount element, radiation performance is excellent and characteristic evaluation at high current can be conducted. Further, the fact that a substrate of light emitting diode 10 is a GaN substrate having high thermal conductivity also contributes to enhancement of radiation performance.

Light emitting diode 10 was placed in a characteristic evaluation apparatus in which a DC current is flown, and blue light emitted from light emitting diode 10 is captured in a full luminous flux. In this case, an action voltage and a main wavelength (center wavelength) are simultaneously monitored.

Light emitting diode 10 having six well layers 51 was prepared as Example 1, and Light emitting diodes 10 having three to five well layers 51 and nine well layers 51 (total thickness of well layer 51 is 36 nm) were prepared as Examples 2 to 5, and then a defective yield due to electric leakage was measured. Herein, defective due to electric leakage was determined by applying a surge voltage to light emitting diode 10, applying a forward bias to a p-n junction so that a p-side was plus (+) and a n-side was minus (−), and monitoring a voltage in injecting 1 ρA. Light emitting diode in which the voltage is 1 V or less was rate as defective.

(Investigated Light Emitting Diode 10)

Here, light emitting diodes 10 described above and later are summarized in Table 1 below. z,999

(Results of Study)

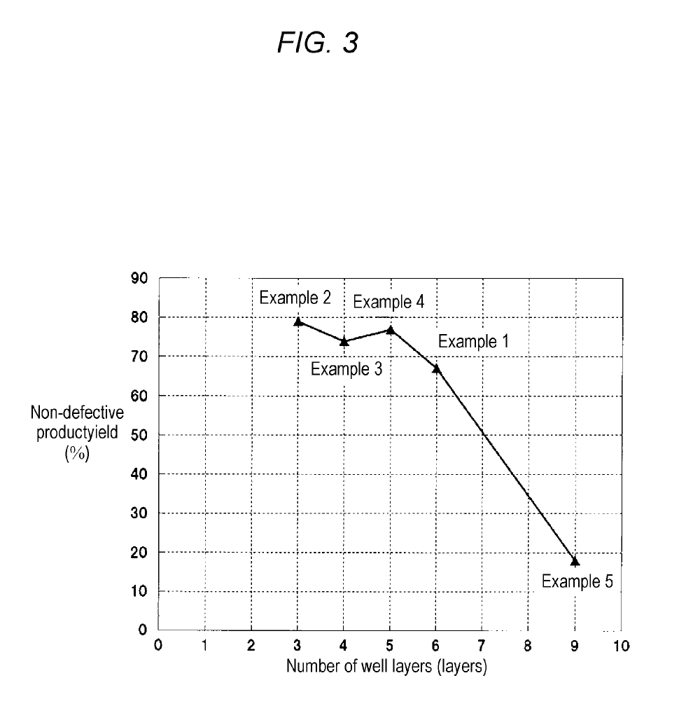

From a graph of FIG. 3, it is found that a non-defective product yield due to electrical leakage is sharply deteriorated when the well layers increase to more than six layers.

Next, in light emitting diode 10, well layer 51 of light-emitting layer 50 was laminated on AlGaN strain adjustment layer 40 in a direct contact manner. A light emitting diode formed by inserting barrier layer 52 between AlGaN strain adjustment layer 40 and well layer 51 was prepared as Comparative Example 1, and an yield of light emitting diodes was measured.

Consequently, the yield of Comparative Example 1 having six well layers was 26%, which was significantly deteriorated when compared with the case of six well layers. This result shows that in light-emitting layer 50 laminated on AlGaN strain adjustment layer 40, well layer 51 is preferably laminated as a layer in contact with AlGaN strain adjustment layer 40.

Next, in light emitting diode 10 (Example 1), barrier layer 52 was made of InGaN and six well layers 51 were set, and light emitting diodes were prepared for Example 2 in which barrier layer 52 was made of InGaN and three well layers 51 were set (total thickness of well layer 51 was 12 nm), Comparative Example 2 in which barrier layer 52 was made of GaN and six well layers 51 were set, and Comparative Example 3 in which barrier layer 52 was made of GaN and three well layers 51 were set, and a light output and strain of the light-emitting layer of each example were measured.

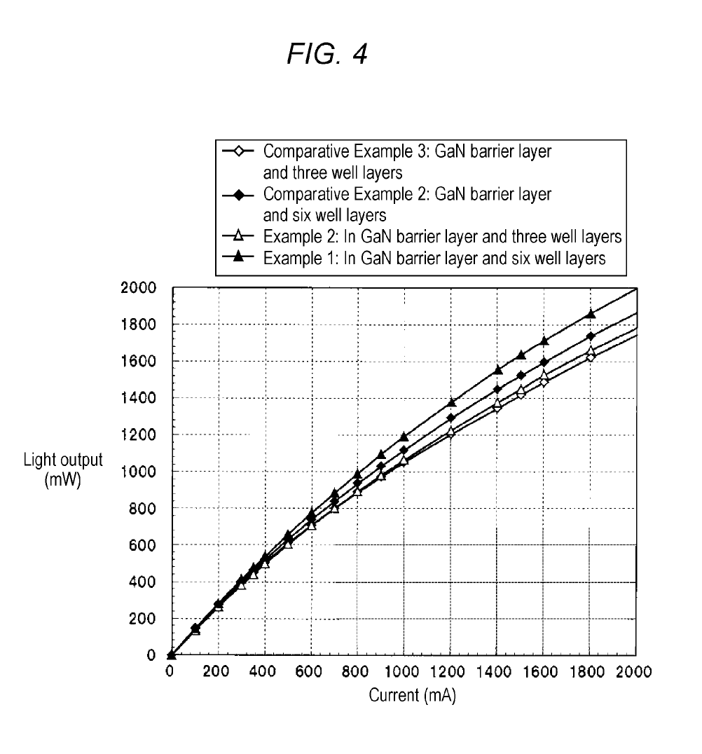

In a range of a current up to 2000 mA (current density; 310 A/cm²) as a maximum injection current, results of measuring a total light output emitted from light emitting diode 10 are shown in FIG. 4. As shown in a graph of FIG. 4, with respect to the light output, Example 1 in which barrier layer 52 was made of InGaN and six well layers 51 were set was highest, and although a size of light emitting diode 10 was as small as 0.8 mm square, luminous efficiency was not reduced up to a large current, a light output linearly increased and, for example, a high light output with a level of 1550 mW at an injection current of 1400 mA (current density; 210 A/cm2) could be obtained. The second highest was Comparative Example 2 in which barrier layer 52 was made of GaN and six well layers 51 were set, the third highest was Example 2 in which barrier layer 52 was made of InGaN and three well layers 51 were set, and Comparative Example 3 was the lowest in which barrier layer 52 was made of GaN and three well layers 51 were set.

Accordingly, it was apparent as follows: when the number of well layers 51 is large, a high light output is exhibited, when barrier layer 52 is made of InGaN rather than GaN, a high light output is exhibited, and it is more effective to increase the number of well layers 51 than to use InGaN as barrier layer 52.

Conventionally, when a white LED for illumination is used for a flash lamp for camera or an vehicle-mounted DRL, the LED is used in a current range of 300 mA to 500 mA, and therefore a difference in light output has not become a problem (refer to FIG. 4). However, when the LED is used for an vehicle-mounted head lamp, the LED is used in a large current range of 1 A or more, for example, 1400 mA to 1600 mA (current density; 150 A/cm² or more), and therefore the difference in light output is remarkable.

In a light emitting diode in which a semiconductor layer including a light-emitting layer is formed on a sapphire substrate widely used as a lamination substrate, a size of the light emitting diode is increased to 1 mm square or more in order to obtain a high light output. The reason for this is that a reactive current increases due to a high density defective (e.g., about 1×10⁹ cm⁻²) in a crystal at a large current injection density of 150 A/cm² or more to generate heat, and thereby the light output is saturated. On the other hand, in light emitting diode 10, it is possible to attain a high light output by the size smaller than 1 mm square, and therefore it is possible to widen individualization of design in an vehicle-mounted head lamp.

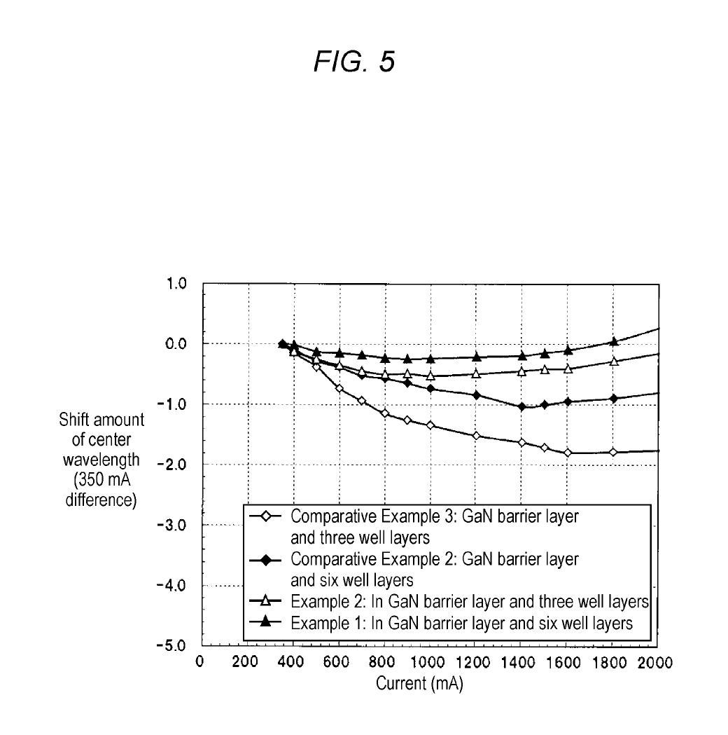

Next, measurement results of strain of the light-emitting layer are shown in FIG. 5. A graph of FIG. 5 shows the results of measuring, as a relative value, a shift amount of a center value of an emission wavelength at the time when an injection current varies in a range of a current up to 2000 mA as a maximum injection current, based on a center value of an emission wavelength at an injection current of 350 mA. When strain is present within the light-emitting layer, a piezo electric field in the well layer is screened together with current injection, and the emission wavelength is shifted to a short wavelength side. That is, by measuring the dependence of the emission wavelength on the injection current, an intensity of piezo electric field of the well layer can be estimated. Accordingly, the smaller the shift amount of the emission wavelength is, the smaller the piezo electric field of the well layer is.

As shown in the graph of FIG. 5, as a whole, Example 1 in which barrier layer 52 was made of InGaN and six well layers 51 were set was the smallest in the shift amount, Comparative Example 2 in which barrier layer 52 was made of GaN and six well layers 51 were set was the second smallest, Example 2 in which barrier layer 52 was made of InGaN and three well layers 51 were set was the third smallest, and Comparative Example 3 barrier layer 52 was made of GaN and three well layers 51 were set was the largest in the shift amount. When the shift amount of a center value of an emission wavelength in a blue color region of the light emitting diode is large, conversion efficiency of an excited phosphor substance is changed, and an output and chromaticity as a white color varies. In particular, in the vehicle-mounted head lamp, the light emitting diode is used at a large current of 1 A or more (e.g., 1400 mA to 1600 mA); however, the light emitting diode also has applications where it is used at a low-current drive as a DRL, and therefore the light emitting diode having a large shift amount of emission wavelength like Comparative Example 3 is not preferred. On the other hand, the shift amount of emission wavelength of Example 1 is extremely small and remains 1 nm or less. Accordingly, the present disclosure firstly enabled appearance of a light emitting diode which can suppress the shift amount of emission wavelength to about 1 nm or less even at a large current of 1 A or more in an LED using GaN substrate having a C-plane as a lamination surface excellent in crystal quality.

Accordingly, it is found as follows: when the number of well layers 51 is large, the strain of light-emitting layer 50 can be more reduced; when barrier layer 52 is made of InGaN rather than GaN, the strain of well layer 51 contributing to light emission can be more reduced; and it is more effective to use InGaN as barrier layer 52 than to increase the number of well layers 51.

Next, a light emitting diode for Example 6 was prepared in which well layer 51 made of InGaN had a thickness of 6 nm and four well layers 51 were set (the total thickness was 24 nm which was the same as in Example 1 in which well layer 51 made of InGaN had a thickness of 4 nm and six well layers 51 were set). Also in Example 6, a light output by current injection was measured, and consequently a high light output almost equal to that of Example 1 could be obtained. Further, it could be confirmed that the shift amount of emission wavelength in Example 6 was similar to that of Example 1. Compared with the case where well layer 51 has a thickness of 4 nm, when the thickness is increased to about 6 nm, in the barrier layer made of GaN, spatial separation of an electron from a hole becomes larger due to a piezo electric field applied to the well layer, and the shift amount of emission wavelength becomes more remarkable. However, when barrier layer 52 is made of InGaN, it is found that the shift amount of emission wavelength can be suppressed to 1 nm or less even when the thickness of well layer 51 is increased to about 6 nm.

From the above, it is found that well layer 51 made of InGaN preferably has a total thickness of 6 to 36 nm, and the barrier layer is also made of InGaN. Moreover, well layer 51 made of InGaN preferably has a total thickness of 10 to 25 nm.

Further, in Example 6, barrier layer 52 made of InGaN had an In composition ratio of 6%; however, when the In composition ratio was increased to 8%, a light-emitting output at 1400 mA was increased by about 4%. Accordingly, it was clear that when the number of well layers 51 made of InGaN is reduced, a high light output can be obtained by increasing the In composition ratio of barrier layer 52 made of InGaN.

A DC electrical test of 1400 mA was performed in Example 1, and as a result, a light output remaining rate was 97% or more after a lapse of 1500 hours, and it could be confirmed that long-term stable driving could be performed even at a large current conducting of 1A or more and it was apparent that the light emitting diode is suitable for an vehicle-mounted head lamp.

Furthermore, to Example 1, a light emitting diode for Example 7 was prepared in which a thickness of barrier layer 52 made of InGaN is set to as thin as 1.8 nm.

Compared with Example 1, a light output at 350 mA was slightly low in Example 7; however, a higher light output was exhibited at a large current region of 1400 mA or more. That is, this suggests that the thickness of barrier layer 52 made of InGaN is set to as thin as 1.8 nm, so that an increase rate of the light output to an injection current increases. The reason for this is supposed that in GaN-based materials, it is known that an effective mass of a hole to an electrode is large as physical properties, and therefore a hole injection from the p-side to light-emitting layer 50 is difficult; however, when the thickness of barrier layer 52 is set to as thin as about 1 to 3 nm, a hole comes to be injected into neighboring well layer 51 in the form of tunneling to improve efficiency of a hole injection up to well layer 51 near the n-side.

It is known that many hollows referred to as V pits resulting from penetrating dislocation are produced at a crystal surface during growth of an InGaN well layer on a sapphire substrate, and it is difficult in terms of commercial production to control a thickness of a barrier layer to be stably about 1 to 3 nm. This trend is remarkable as the InGaN well layer is multiplexed.

On the other hand, as with Example 7, V pits are hardly produced on a GaN substrate having a C-plane, so that it is possible to stably produce a light emitting diode of high quality even when the thickness of the barrier layer is made thin. However, when the thickness of barrier layer 52 is less than 1 nm, it is not preferred since it is difficult to control crystal growth itself, and a production yield is deteriorated. Further, in Example 7, it could be verified that the shift amount of emission wavelength is also equal to that of Example 1. When the thickness of barrier layer 52 is made thin, it is trend to obtain a high light output by increasing the In composition ratio of barrier layer 52 as with Example 6.

While the size of the light emitting diode was 0.8 mm square in Example 1, in Example 8, a light emitting diode having a size of 0.6 mm square was prepared. A configuration of light-emitting layer 50 of Example 8 is the same as that of Example 1, and well layer 51 made of InGaN has a thickness of 4 nm and six well layers 51 are set (a total thickness of well layer 51 is 24 nm). In Example 8, a high light output of 1300 mW could also be attained at 1400 mA (current density; 380 A/cm²) in spite of a smaller size. Further, in a range of a current up to 2000 mA (current density; 550 A/cm²) as a maximum current, it could also be confirmed that the shift amount of a center value of an emission wavelength was suppressed to 1 nm or less. There is no light emitting diode using a GaN substrate in which the shift amount of emission wavelength is suppressed to 1 nm or less even in such an extremely large injection current density, and the effect of strain control by the present disclosure is remarkable, and the light emitting diode is suitable as vehicle-mounted head lamps.

The present disclosure can attain high quality and a high light output by suppressing luminous efficiency deterioration even if a lamination surface of a GaN substrate is a C-plane, and therefore the present disclosure is suitable for a light emitting diode including a GaN substrate, an n-type GaN layer, a light-emitting layer layer having a multi-quantum well structure based on a gallium nitride-based semiconductor, and a p-type AlGaN clad layer.

What is claimed is:

1. A light emitting diode comprising:
a GaN substrate having a C-plane as a lamination surface;
an n-type GaN layer laminated on the GaN substrate;
an AlGaN layer laminated on the n-type GaN layer;
a light-emitting layer which is laminated on the AlGaN layer and which has a multi-quantum well structure having well layers and a barrier layer, the well layers and the barrier layer containing a gallium nitride-based semiconductor having a lattice constant in an a-axis direction larger than a lattice constant of the AlGaN layer in the a-axis direction; and
a p-type AlGaN layer laminated on the light emitting layer.

2. The light emitting diode according to claim 1, wherein the AlGaN layer has a thickness ranging from 2 nm to 10 nm inclusive.

3. The light emitting diode according to claim 1, wherein the light-emitting layer is a semiconductor layer having a lattice constant in an a-axis direction larger than a lattice constant of the n-type GaN layer in the a-axis direction.

4. The light emitting diode according to claim 1, wherein in the light-emitting layer, the semiconductor layer laminated directly on the AlGaN layer is one of the well layers.

5. The light emitting diode according to claim 1, wherein the AlGaN layer has an Al composition ratio ranging from 1% to 5% inclusive.

6. The light emitting diode according to claim 1, wherein the well layers and the barrier layer each are made of InGaN.

7. The light emitting diode according to claim 6, wherein the well layers each made of the InGaN have a total thickness ranging of from 6 nm to 36 nm inclusive.

8. The light emitting diode according to claim 1, wherein in a range of a current up to 2000 mA as a maximum injection current which flows from the p-type AlGaN layer to the n-type GaN layer, a shift amount of a center value of an emission wavelength at the current relative to a center value at an injection current of 350 mA is 1 nm or less.
